(19) United States
(12) Patent Application Publication
(10) Pub. No.: US 2023/0127806 A1
(43) Pub. Date: Apr. 27, 2023

(54) SUBSTRATE SUPPORT TEMPERATURE PROBE DIAGNOSTICS AND MANAGEMENT

(71) Applicant: LAM RESEARCH CORPORATION, Fremont, CA (US)

(72) Inventors: Anthony John RICCI, Redwood City, CA (US); Keith GAFF, Fremont, CA (US)

(21) Appl. No.: 17/914,499

(22) PCT Filed: Mar. 27, 2020
(86) PCT No.: PCT/US2020/025540

§ 371 Date: Sep. 26, 2022

(51) Int. Cl. H01J 37/32

(52) U.S. Cl. CPC H01J 37/32724; H01J 37/32935; H01J 37/32926; H01J 37/3299

(57) ABSTRACT

A substrate processing system includes: a substrate support within a processing chamber to vertically support a substrate; a temperature probe including: a first temperature sensor to measure a first temperature of the substrate support; a second temperature sensor to measure a second temperature of the substrate support; a third temperature sensor to measure a third temperature of the substrate support; and a fourth temperature sensor to measure a fourth temperature of the substrate support; a temperature module to: in a first state, determine a substrate support temperature of the substrate support based on the first, second, third, and fourth temperatures; in a second state, determine the substrate support temperature based on only three of the first, second, third, and fourth temperatures; and a temperature control module configured to control at least one of heating and cooling of the substrate support based on the substrate support temperature.

### FIELD

The present disclosure relates to temperature probes of baseplates of substrates supports of substrate processing systems and more particularly to diagnosing and utilizing measurements of temperature sensors of temperature probes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures may be introduced into the processing chamber and plasma may be used to initiate chemical reactions.

### SUMMARY

In a feature, a substrate processing system includes: a substrate support within a processing chamber to vertically support a substrate; a temperature probe including: a first temperature sensor to measure a first temperature of the substrate support; a second temperature sensor to measure a second temperature of the substrate support; a third temperature sensor to measure a third temperature of the substrate support; and a fourth temperature sensor to measure a fourth temperature of the substrate support; a temperature module to: in a first state, determine a substrate support temperature of the substrate support based on all of the first, second, third, and fourth temperatures; in a second state, determine the substrate support temperature of the substrate support based on only three of the first, second, third, and fourth temperatures; and a temperature control module configured to control at least one of heating and cooling of the substrate support based on the substrate support temperature.

In further features, the temperature module is to set the substrate support temperature based on an average of the at least three of the first, second, third, and fourth temperatures.

In further features: the substrate support includes: an upper portion to vertically support the substrate; and a baseplate to vertically support the upper portion; the first temperature sensor is to measure the first temperature of the baseplate; the second temperature sensor to measure the second temperature of the substrate support; the third temperature sensor is to measure the third temperature of the substrate support; and the fourth temperature sensor is to measure the fourth temperature of the substrate support.

In further features: the substrate support includes: an upper portion to vertically support the substrate; and a baseplate to vertically support the upper portion; the first temperature sensor is to measure the first temperature of the upper portion; the second temperature sensor to measure the second temperature of the upper portion; the third temperature sensor is to measure the third temperature of the upper portion; and the fourth temperature sensor is to measure the fourth temperature of the upper portion.

In further features, the temperature module is to determine the substrate support temperature based on at least three of: a first average of X of the first temperatures, wherein X is an integer greater than one; a second average of X of the second temperatures; a third average of X of the third temperatures; and a fourth average of X of the fourth temperatures.

In further features, the temperature module is to determine the substrate support temperature based on an average of the at least three of the first average, the second average, the third average, and the fourth average.

In further features, the temperature module is to determine the substrate support temperature based on all of the first, second, third, and fourth averages when a first difference between a maximum one of the first, second, third, and fourth averages and a minimum one of the first, second, third, and fourth averages is less than a temperature.

In further features, the temperature module is to selectively determine the substrate support temperature based on three of the first, second, third, and fourth averages when the first difference is greater than the substrate support temperature.

In further features, the temperature module is to determine the substrate support temperature based on the first, second, and third average and not based on the fourth average when a second difference between a second maximum one of the first, second, and third averages and a second minimum one of the first, second, and third averages is less than the substrate support temperature.

In further features, the temperature module is to determine the substrate support temperature based on the first, second, and fourth average and not based on the third average when a third difference between a third maximum one of the first, second, and fourth averages and a third minimum one of the first, second, and fourth averages is less than the substrate support temperature.

In further features, the temperature module is to determine the substrate support temperature based on the first, third, and fourth average and not based on the second average when a fourth difference between a fourth maximum one of the first, third, and fourth averages and a fourth minimum one of the first, third, and fourth averages is less than the substrate support temperature.

In further features, the temperature module is to determine the substrate support temperature based on the second, third, and fourth average and not based on the first average when a fifth difference between a fifth maximum one of the second, third, and fourth averages and a fifth minimum one of the second, third, and fourth averages is less than the substrate support temperature.

In further features, a diagnostic module is to indicate that a fault is present in the temperature probe when the first, second, third, fourth, and fifth differences are greater than the substrate support temperature.

In further features, the diagnostic module is to display an alert on a display when the fault is present in the temperature probe.

In further features, the first, second, third, and fourth temperature sensors are solid state temperature sensors.

In further features, a thermally conductive material is sandwiched between the substrate support and the first, second, third, and fourth temperature sensors.

In further features: a statistics module is to: determine a first average of a plurality of values of the first temperature; determine a second average of a plurality of values of the first average; determine a first standard deviation of the plurality of values of the first average; determine a second standard deviation of a plurality of timestamps associated with the plurality of values of the first average; determine a correlation coefficient based on the plurality of timestamps and the plurality of values of the first average; determine a slope based on the correlation coefficient, the first standard deviation, and the second standard deviation; and a diagnostic module is to diagnose whether the slope is within a slope range.

In further features, the statistics module is to determine the correlation coefficient based on (a) a covariance of the plurality of values of the first average and the plurality of timestamps, (b) the first standard deviation, and (c) the second standard deviation.

In further features, the statistics module is to set the slope based on the correlation coefficient multiplied by the first standard deviation divided by the second standard deviation.

In further features, the temperature control module is to at least one of: selectively apply power to a thermal control element (TCE) based on the substrate support temperature; and selectively adjust coolant flow through coolant channels in the substrate support based on the substrate support temperature.

In a feature, a substrate processing system includes: a substrate support within a processing chamber to vertically support a substrate; a temperature probe including: N temperature sensor to measure N temperatures of the substrate support, wherein N is an integer greater than 3; a temperature module to: in a first state, determine a substrate support temperature of the substrate support based on all of the N temperatures; in a second state, determine the substrate support temperature of the substrate support based on a subset of the N temperatures; and a temperature control module to control at least one of heating and cooling of the substrate support based on the substrate support temperature. In various implementations, the subset is only N−1 of the N temperatures.

In a feature, a method includes: by a first temperature sensor of a temperature probe, measuring a first temperature of a substrate support that vertically supports a substrate during substrate processing; by a second temperature sensor of the temperature probe, measuring a second temperature of the substrate support; by a third temperature sensor of the temperature probe, measuring a third temperature of the substrate support; by a fourth temperature sensor of the temperature probe, measuring a fourth temperature of the substrate support; in a first state, determining a substrate support temperature of the substrate support based on all of the first, second, third, and fourth temperatures; in a second state, determining the substrate support temperature of the substrate support based on only three of the first, second, third, and fourth temperatures; and controlling at least one of heating and cooling of the substrate support based on the substrate support temperature.

In further features, determining the substrate support temperature includes setting the support temperature based on an average of the at least three of the first, second, third, and fourth temperatures.

In further features: the substrate support includes: an upper portion to vertically support the substrate; and a baseplate to vertically support the upper portion; the measuring the first temperature includes measuring the first temperature of the baseplate; the measuring the second temperature includes measuring the second temperature of the substrate support; the measuring the third temperature includes measuring the third temperature of the substrate support; and the measuring the fourth temperature includes measuring the fourth temperature of the substrate support.

In further features: the substrate support includes: an upper portion to vertically support the substrate; and a baseplate to vertically support the upper portion; the measuring the first temperature includes measuring the first temperature of the upper portion; the measuring the second temperature includes measuring the second temperature of the upper portion; the measuring the third temperature includes measuring the third temperature of the upper portion; and the measuring the fourth temperature includes measuring the fourth temperature of the upper portion.

In further features, determining the substrate support temperature includes determining the substrate support temperature based on at least three of: a first average of X of the first temperatures, wherein X is an integer greater than one; a second average of X of the second temperatures; a third average of X of the third temperatures; and a fourth average of X of the fourth temperatures.

In further features, determining the substrate support temperature includes determining the substrate support temperature based on an average of the at least three of the first average, the second average, the third average, and the fourth average.

In further features, determining the substrate support temperature includes determining the substrate support temperature based on all of the first, second, third, and fourth averages when a first difference between a maximum one of the first, second, third, and fourth averages and a minimum one of the first, second, third, and fourth averages is less than a temperature.

In further features, determining the substrate support temperature includes determining the substrate support temperature based on three of the first, second, third, and fourth averages when the first difference is greater than the substrate support temperature.

In further features, determining the substrate support temperature includes determining the substrate support temperature based on the first, second, and third average and not based on the fourth average when a second difference between a second maximum one of the first, second, and third averages and a second minimum one of the first, second, and third averages is less than the substrate support temperature.

In further features, determining the substrate support temperature includes determining the substrate support temperature based on the first, second, and fourth average and not based on the third average when a third difference between a third maximum one of the first, second, and fourth averages and a third minimum one of the first, second, and fourth averages is less than the substrate support temperature.

In further features, determining the substrate support temperature includes determining the substrate support temperature based on the first, third, and fourth average and not based on the second average when a fourth difference between a fourth maximum one of the first, third, and fourth averages and a fourth minimum one of the first, third, and fourth averages is less than the substrate support temperature.

In further features, determining the substrate support temperature includes determining the substrate support temperature based on the second, third, and fourth average and not based on the first average when a fifth difference between a fifth maximum one of the second, third, and fourth averages and a fifth minimum one of the second, third, and fourth averages is less than the substrate support temperature.

In further features, the method further includes indicating that a fault is present in the temperature probe when the first, second, third, fourth, and fifth differences are greater than the substrate support temperature.

In further features, the method further includes displaying an alert on a display when the fault is present in the temperature probe.

In further features, the first, second, third, and fourth temperature sensors are solid state temperature sensors.

In further features, a thermally conductive material is sandwiched between the substrate support and the first, second, third, and fourth temperature sensors.

In further features, the method further includes: determining a first average of a plurality of values of the first temperature; determining a second average of a plurality of values of the first average; determining a first standard deviation of the plurality of values of the first average; determining a second standard deviation of a plurality of timestamps associated with the plurality of values of the first average; determining a correlation coefficient based on the plurality of timestamps and the plurality of values of the first average; determining a slope based on the correlation coefficient, the first standard deviation, and the second standard deviation; and diagnosing whether the slope is within a slope range.

In further features, determining the correlation coefficient includes determining the correlation coefficient based on (a) a covariance of the plurality of values of the first average and the plurality of timestamps, (b) the first standard deviation, and (c) the second standard deviation.

In further features, determining the slope includes setting the slope based on the correlation coefficient multiplied by the first standard deviation divided by the second standard deviation.

In further features, controlling at least one of heating and cooling of the substrate support includes at least one of: selectively applying power to a thermal control element (TCE) based on the substrate support temperature; and selectively adjusting coolant flow through coolant channels in the substrate support based on the substrate support temperature.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example processing chamber;

FIG. 2 is a cross-sectional view of a portion of an example substrate support;

FIG. 3 is a cross-sectional view including a portion of the substrate support, a temperature probe, and a thermal conductor;

FIG. 4 includes a perspective view of an example implementation of a circuit board and a temperature probe and a close-up view of a portion of the circuit board and the temperature probe;

FIG. 5 is a functional block diagram of an example diagnostic and control system; and

FIGS. 6-9 include a flowchart depicting an example method of determining a baseplate temperature and managing the use of first, second, third, and fourth temperatures from temperature sensors of a temperature probe.

In the drawings, reference numbers may be reused to identify similar and/or identical elements.

### DETAILED DESCRIPTION

A substrate support, such as an electrostatic chuck, supports a substrate in a substrate processing chamber. A substrate is arranged on a ceramic portion of the substrate support during processing. A plurality of thermal control elements may be embedded in the substrate support. The thermal control elements may be controlled to at least one of heat and cool the substrate support. The substrate support includes a baseplate. The baseplate may serve as a heat sink for the thermal control elements. Coolant may be pumped through coolant channels in the baseplate to cool the substrate support.

A single temperature sensor can measure a temperature of the substrate support, such as a temperature of the baseplate. If that single temperature sensor fails, however, substrate processing may be discontinued while the single temperature sensor (and possibly one or more other components that are integrated with the single temperature sensor) is replaced or the fault is otherwise remedied.

The present application involves a temperature probe including N different temperature sensors to measure N temperatures at a location of the substrate support. N is an integer greater than 3. Use of the N temperature sensors provides redundancy and allows substrate processing to continue in the event that one of the N temperature sensors, for example, fails or drops out of communication.

When the N temperatures are within a first range of each other, the N temperatures may be used to determine a temperature of the substrate support. The N temperature sensors may not be calibrated after installation. Measurement precision of the temperature sensors may be confirmed by the N temperatures being within the first range of each other.

When at least one of the N temperatures is outside of the first range, N−1 of the temperatures that are within the range of each other are used to determine the temperature of the substrate support. Measurement precision of those temperature sensors may be confirmed by the N−1 temperatures being within the range of each other.

When no combination of N−1 of the temperatures are within the range of each other, a fault is diagnosed in the temperature probe. Transitioning from use of the N temperatures to use of N−1 of the temperatures may be performed when a change in the temperature of the substrate support would be less than a maximum change. Since the temperatures are used to control the temperature of the substrate support, the above prevents the temperature of the substrate support from changing by more than an allowed amount.

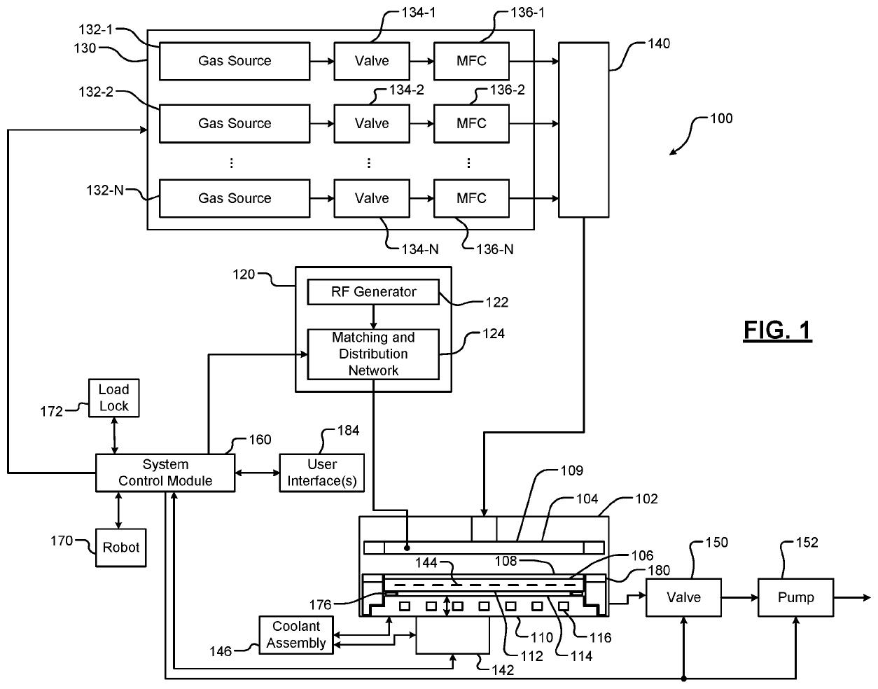

Referring now to FIG. 1, an example substrate processing system 100 is shown. For example only, the substrate processing system 100 may be used for performing etching using a radio frequency (RF) plasma.

The substrate processing system 100 includes a processing chamber 102 that encloses other components of the substrate processing system 100 and that contains the RF plasma. The processing chamber 102 includes an upper electrode 104 and a substrate support 106, such as an electrostatic chuck (ESC).

During operation, a substrate 108 is arranged on the substrate support 106. An example of the substrate processing system 100 and the processing chamber 102 is shown. However, the present application is also applicable to other types of substrate processing systems and processing chambers, such substrate processing systems that generate plasma in-situ, substrate processing systems that implement remote plasma generation and delivery (e.g., using a plasma tube, a microwave tube), etc.

The upper electrode 104 may include a gas distribution device, such as a showerhead 109, that introduces and distributes process gases within the processing chamber 102. The showerhead 109 may include a stem portion including one end connected to a top surface of the processing chamber 102. A base portion of the showerhead 109 is generally cylindrical and extends radially outwardly from an opposite end of the stem portion at a location that is spaced from the top surface of the processing chamber 102. A substrate-facing surface, or faceplate, of the base portion of the showerhead 109 includes a plurality of holes through which process gas or purge gas flows. Alternatively, the upper electrode 104 may include a conducting plate and the process gases may be introduced in another manner.

The substrate support 106 includes an electrically conductive baseplate 110 that acts as a lower electrode. The baseplate 110 supports a ceramic layer 112. One or more other layers 114 may be arranged between the ceramic layer 112 and the baseplate 110.

The baseplate 110 may include one or more coolant channels 116 for flowing coolant through the baseplate 110. In some examples, a protective seal 176 may be provided.

An RF generating system 120 generates and outputs an RF voltage to one of the upper electrode 104 and the lower electrode (e.g., the baseplate 110 of the substrate support 106) to strike and maintain plasma within the processing chamber 102. The other one of the upper electrode 104 and the baseplate 110 may be direct current (DC) grounded, alternating current (AC) grounded, or floating. For example only, the RF generating system 120 may include an RF voltage generator 122 that generates the RF voltage that is fed by a matching and distribution network 124 to the upper electrode 104 or the baseplate 110.

A gas delivery system 130 includes one or more gas sources 132-1, 132-2, . . . , and 132-N (collectively gas sources 132), where N is an integer greater than zero. The gas sources 132 supply one or more etch gases, carrier gases, inert gases, precursor gases, and mixtures thereof. The gas sources 132 may also supply purge gas and other types of gas.

The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109 and output to the processing chamber 102 from the showerhead 109.

A temperature control module 142 is connected to an array of heating elements within the substrate support 106, such as thermal control elements (TCEs) 144 arranged in the ceramic layer 112. For example, the TCEs 144 may include, but are not limited to, macro heating elements corresponding to respective zones in a multi-zone heating plate and/or an array of micro heating elements disposed across multiple zones of a multi-zone heating plate. The TCEs 144 may be, for example, (electrically) resistive heaters that generate heat when power is applied to the heaters, respectively, or another suitable type of heating element.

The temperature control module 142 controls the application of power to the TCEs 144 to control temperatures at various locations on the substrate support 106 and the substrate 108. For example, the temperature control module 142 may control respective switches to connect and disconnect the TCEs 144 to and from power.

The temperature control module 142 may communicate with a coolant assembly 146 to control coolant flow through the coolant channels 116 in the baseplate 110. For example, the coolant assembly 146 may include a coolant pump, reservoir, and one or more heat exchangers. The temperature control module 142 operates the coolant assembly 146 (e.g., the coolant pump) to selectively flow the coolant through the coolant channels 116 to cool the substrate support 106. The temperature control module 142 may also control a speed of the coolant pump to control a flowrate of coolant through the coolant channels 116. The temperature control module 142 may control the TCEs 144 together with the coolant assembly 146, for example, to achieve one or more target temperatures.

A valve 150 and pump 152 may be used to evacuate reactants from the processing chamber 102. A system control module 160 may control components of the substrate processing system 100. Although shown as separate controllers, the temperature control module 142 may be implemented within the system control module 160.

A robot 170 may deliver substrates onto, and remove substrates from, the substrate support 106. For example, the robot 170 may transfer substrates between the substrate support 106 and a load lock 172.

In some examples, the substrate support 106 includes an edge ring 180. The edge ring 180 may be moveable (e.g., moveable upward and downward in a vertical direction) relative to the substrate 108. For example, movement of the edge ring 180 may be controlled via one or more actuators responsive to input from the system control module 160. In some examples, a user may input control parameters to the system control module 160 via one or more user interface devices 184, which may include one or more input and/or output devices (e.g., keyboard, mouse, touchscreen), a display, etc.

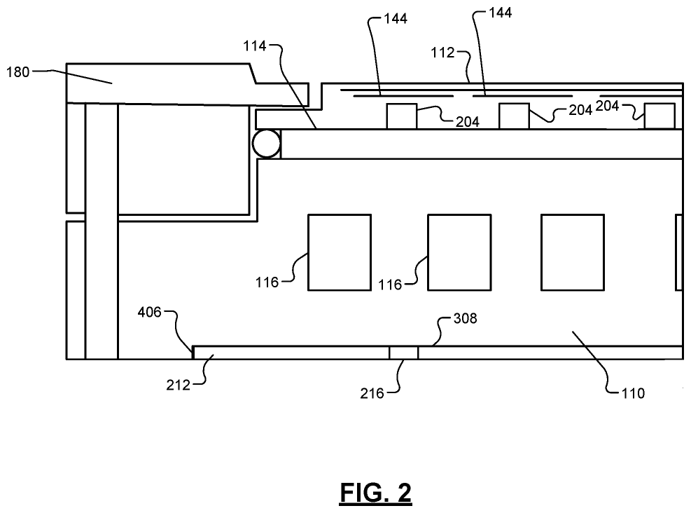

FIG. 2 includes a cross-sectional view of a portion of an example implementation of the substrate support 106. The TCEs 144 may be embedded in the ceramic layer 112. A plurality of temperature sensors (or temperature probes) 204 may also be embedded in the ceramic layer 112. The temperature sensors 204 may be spaced apart from each other one of the temperature sensors 204 or grouped in proximity to one or more other ones of the temperature sensors 204. In various implementations, the ceramic layer 112 may include one or more temperature sensors per TCE. The temperature sensors 204 may be located proximate to (e.g., within a predetermined distance of) the TCEs 144, respectively. For example, the temperature sensors 204 may be located between the TCEs 144, respectively, and the baseplate 110. The temperature sensors 204 measure temperatures at their respective locations.

The TCEs 144 are controlled by the temperature control module 142. The temperature control module 142 may control the application of power to the TCEs 144 individually. For example, switches may be connected in series with the TCEs 144, respectively, and the temperature control module 142 may control the switches to control the application of power to the TCEs 144, respectively. In various implementations, the temperature control module 142 may control the application of power to groups of two or more of the TCEs 144. For example, switches may be connected in series with groups of two or more the TCEs 144, and the temperature control module 142 may control the switches to control the application of power to the groups, respectively. The baseplate 110 may be a monolithic piece or include multiple pieces.

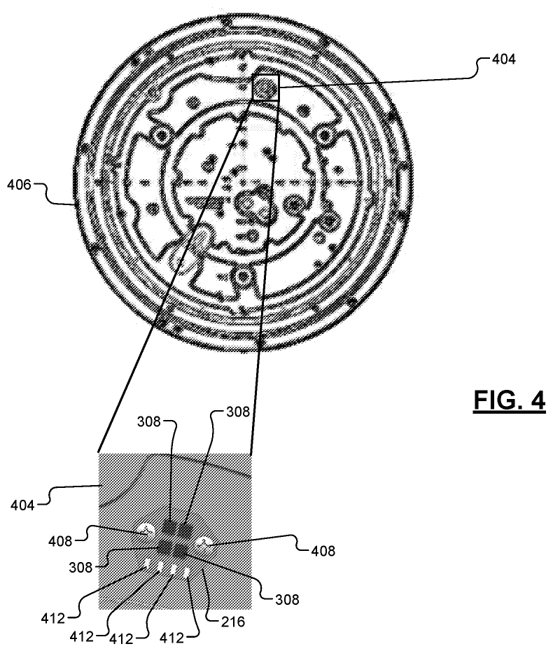

The temperature control module 142 may be implemented on a circuit board 208 that is fixed within a recess 212 in a lower surface of the baseplate 110. A temperature probe 216 may also be implemented on a circuit board 406, such as shown in FIG. 4. The temperature probe 216 includes temperature sensors that measure temperatures, respectively, of the baseplate 110.

The temperature control module 142 receives the temperatures measured by the temperature sensors 204 and the temperatures measured by the temperature probe 216. The temperature control module 142 controls at least one of the TCEs 144 and the coolant assembly 146 based on at least one of (i) the temperatures measured by the temperature sensors 204 and (ii) the temperatures measured by the temperature probe 216. For example, the temperature control module 142 may control one or more of the TCEs 144 to adjust the temperature measured by one of the temperature sensors 204 associated with the corresponding TCE 144 toward a target temperature. As another example, the temperature control module 142 may control the coolant assembly 146 to control a flowrate of coolant through the coolant channels 116 based on one or more of the temperatures measured by the temperature probe 216.

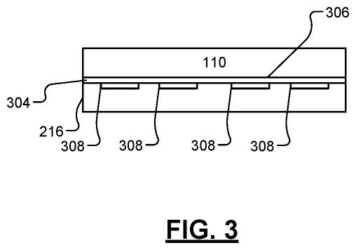

FIG. 3 is a cross-sectional view including a portion of the substrate support 106 (e.g., the baseplate 110), the temperature probe 216, and a thermal conductor 304. The thermal conductor 304 may be made of a thermally conductive material (e.g., a paste) and may be sandwiched between the temperature probe 216 and a bottom surface 306 of the baseplate 110. Example temperature sensors 308 of the temperature probe 216 are illustrated. The temperature sensors 308 of the temperature probe 216 may contact the thermal conductor 304. The thermal conductor 304 may be configured to transfer heat equally such that each of the of the temperature sensors 308 should measure the same temperature within a predetermined tolerance. The temperature sensors 308 may be, for example, solid state temperature sensors. An accuracy of the temperature sensors 308 may be, for example, +/−0.5 degrees Celsius or less. In various implementations, the thermal conductor 304 may be omitted, and the temperature sensors 308 may directly contact the bottom surface 306 of the baseplate 110.

FIG. 4 is a perspective view of an example implementation of the circuit board 406 and the temperature probe 216 taken from the side of the circuit board 406 that faces the bottom surface 306 of the baseplate 110. FIG. 4 also includes a close-up view 404 of a portion of the circuit board 406 and the temperature probe 216.

In various implementations, the temperature sensors 308 may be arranged in two rows and two columns, where each of the temperature sensors 308 is located in one row and one column. The temperature sensors 308, however, may be located and arranged differently. As shown, the temperature probe 216 may include the four temperature sensors 308. Stated more generally, the temperature probe 216 includes N temperature sensors, where N is an integer greater than three.

The temperature probe 216 may be fixed to the circuit board 208, such as using one or more fasteners 408 or in another suitable manner. The temperature probe 216 includes conductors 412 that are electrically connected to the temperature sensors 308, respectively. Electrical conductors (e.g., traces and/or wires) electrically connect the conductors 412 with the temperature control module 142 to communicate temperatures measured by the temperature sensors 308 to the temperature control module 142.

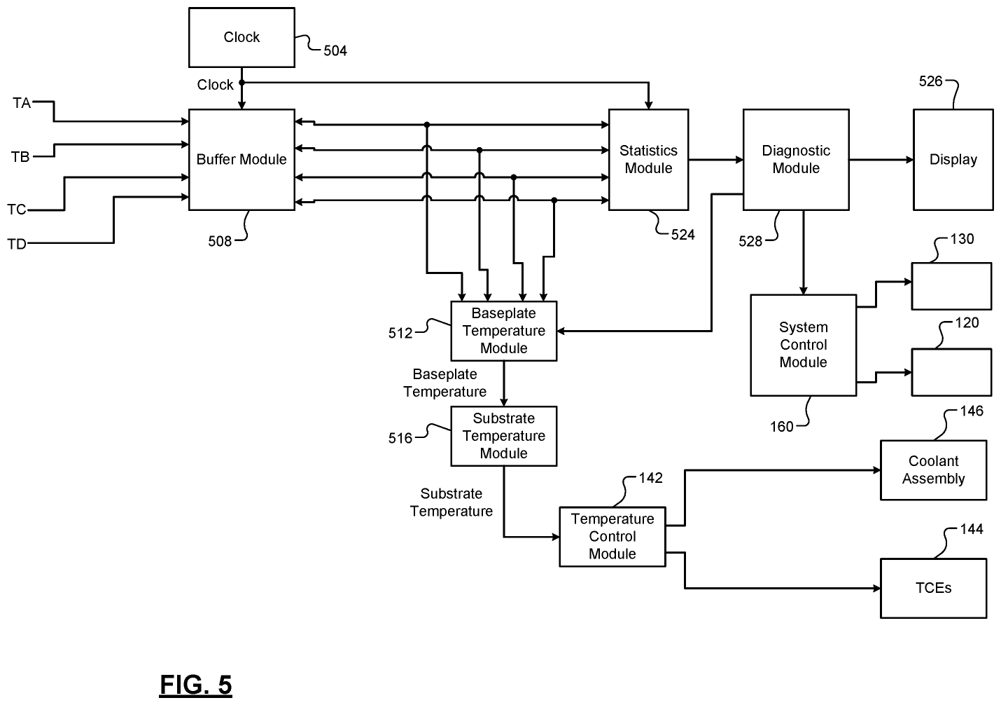

FIG. 5 is a functional block diagram of an example diagnostic and control system. A clock 504 selectively generates timestamps during substrate processing. The clock 504 may generate a timestamp at a clock frequency, such as 20 Hertz or another suitable frequency. As such, the clock 504 generates a timestamp every period, where the period is equal to 1 divided by the clock frequency.

A buffer module 508 is electrically connected to each the temperature sensors 308 of the temperature probe 216. The buffer module 508 receives a first temperature (TA) measured by a first one of the temperature sensors 308, a second temperature (TB) measured by a second one of the temperature sensors 308, a third temperature (TC) measured by a third one of the temperature sensors 308, and a fourth temperature (TD) measured by a fourth one of the temperature sensors 308. The buffer module 508 stores the first, second, third, and fourth temperatures each time a timestamp is generated. The buffer module 508 also stores the timestamps.

The buffer module 508 stores at least a number (X) of sets of the temperatures and timestamps. The number (X) may be calibrated and may be set to, for example, 20 or another suitable integer. The stored values are used to generate statistical values, as discussed further below. For ones of the temperature sensors 308 that drop out or are determined to be providing invalid temperatures, the buffer module 508 may store temperature values of zero (0) Kelvin. While the example of temperatures in Kelvin is provided, other suitable units of temperature may be used.

During the substrate processing, a baseplate temperature module 512 determines a temperature of the baseplate 110 based on three or more of the first, second, third, and fourth temperatures. The temperature of the baseplate 110 will be referred to as a baseplate temperature. For example, the baseplate temperature module 512 may set the baseplate temperature based on or equal to an average of the three or more of the temperatures. The baseplate temperature module 512 may determine which three or more of the temperatures to use to determine the baseplate temperature as discussed further below.

During the substrate processing, a substrate temperature module 516 determines a temperature of the substrate 108 on the substrate support 106 based on the baseplate temperature. The substrate temperature module 516 may determine the temperature of the substrate 108 further based on one or more other operating parameters, such as one or more temperatures measured by one or more of the temperature sensors 204. The substrate temperature module 516 may determine the temperature of the substrate 108, for example, using one or more equations and/or lookup tables that relate the baseplate temperature and the other operating parameters to substrate temperatures.

During the substrate processing, the temperature control module 142 controls at least one of heating and cooling of the substrate support 106 based on the substrate temperature. For example, the temperature control module 142 may adjust a flowrate of coolant through the coolant channels 116 via the coolant assembly 146 based on the substrate temperature. The temperature control module 142 may adjust the flowrate, for example, to adjust the substrate temperature toward or to a target temperature. Additionally or alternatively, the temperature control module 142 may control one or more of the TCEs 144 based on the substrate temperature. For example, the temperature control module 142 may control one or more of the TCEs 144 to adjust the substrate temperature toward or to a target temperature.

A statistics module 524 determines various statistical values during the substrate processing based on temperatures and other parameters stored by the buffer module 508, as discussed further below. As also discussed further below, a diagnostic module 528 diagnoses whether a fault is present in the temperature probe 216 based on one or more of the statistics values.

The diagnostic module 528 may take one or more actions when a fault is present in the temperature probe 216. For example, the diagnostic module 528 may display a predetermined message associated with the fault in the temperature probe 216 on a display 526. Additionally or alternatively, the diagnostic module 528 may prompt the system control module 160 to stop the substrate processing when the fault is present in the temperature probe 216. For example, the diagnostic module 528 may prompt the system control module 160 to actuate the gas delivery system 130 (e.g., close the valves 134) and stop the flow of one or more gasses to the processing chamber 102. Additionally or alternatively, the diagnostic module 528 may prompt the system control module 160 to adjust the RF generating system 120 to stop applying power to one, more than one, or all components within the processing chamber 102. The diagnostic module 528 may clear the fault and allow substrate processing to be performed in response to receipt of user input to acknowledge the presence of the fault and to clear the fault.

The diagnostic module 528 also sets first and second signals based on the statistical values during the substrate processing. The first signal may be, for example, a first flag (e.g., Flag A) or another suitable type of signal. The second signal may be, for example, a second flag (e.g., Flag B) or another suitable type of signal. The state of the first signal indicates how many of the temperature sensors 308 are used to determine the baseplate temperature. The state of the second signal indicates to the baseplate temperature module 512 which ones of the temperature sensors 308 to use the stored temperatures from to determine the baseplate temperature. Setting of the state of the first and second signals is discussed further below.

Generally stated, when all four of the temperature sensors 308 are within a first temperature range, the baseplate temperature module 512 determines the baseplate temperature based on the stored first, second, third, and fourth temperatures. The first temperature range may be calibrated and may be, for example, approximately 1 degree Celsius or another suitable range. When all four of the temperature sensors 308 are not within the first temperature range, the diagnostic module 528 determines which three of the four temperature sensors 308 are within the temperature range. If three of the four temperature sensors 308 are within the temperature range, the diagnostic module 528 determines whether these three of the four temperature sensors 308 are within a second temperature of a previous (e.g., last) baseplate temperature. The baseplate temperature module 512 determines the baseplate temperature based on those three of the four temperature sensors 308. This allows the utilization of three of the four temperature sensors 308 to determine the baseplate temperature when switching to using three of the four temperature sensors 308 will not cause a change in the baseplate temperature measurement of more than the second temperature and the three of the four temperature sensors 308 are within the first temperature range. This may achieve a required precision. The second temperature may be calibrated or input to a calibration and may be, for example, approximately 0.5 degrees Celsius, 0.25 degrees Celsius, or another suitable temperature.

When no combination of three of the four temperature sensors 308 is within the second temperature of the previous baseplate temperature, the diagnostic module 528 disables the baseplate temperature module 512, diagnoses the fault in the temperature probe 216, and may take one or more actions. Disabling the baseplate temperature module 512 disables the determination of the baseplate temperature. The diagnostic module 528 re-enables the baseplate temperature module 512 when the fault in the temperature probe 216 is cleared.

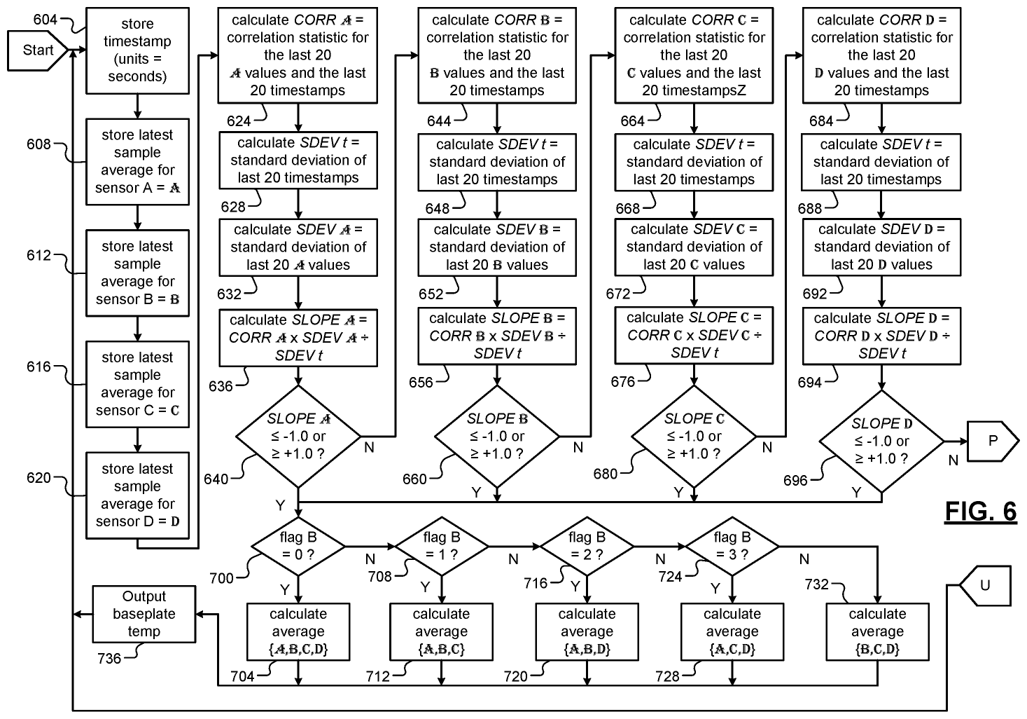

FIGS. 6-9 include a flowchart depicting an example method of determining the baseplate temperature and managing the use of the first, second, third, and fourth temperatures from the temperature sensors 308. Control begins with 604 when the clock 504 generates a timestamp. The buffer module 508 stores the timestamp at 604. At 608, the buffer module 508 stores the sample of the first temperature (TA), and the statistics module 524 determines a first average of the number (e.g., 20) of the most recently stored values of the first temperatures (TA). The statistics module 524 may set the first average based on or equal to a sum of the number (e.g., 20) of the most recently stored values of the first temperature divided by the number (e.g., 20). The buffer module 508 stores the first average.

At 612, the buffer module 508 stores the sample of the second temperature (TB), and the statistics module 524 determines a second average of the number (e.g., 20) of the most recently stored values of the second temperatures (TB). The statistics module 524 may set the second average based on or equal to a sum of the number (e.g., 20) of the most recently stored values of the second temperature divided by the number (e.g., 20). The buffer module 508 stores the second average.

At 616, the buffer module 508 stores the sample of the third temperature (TC), and the statistics module 524 determines a third average of the number (e.g., 20) of the most recently stored values of the third temperatures (TC). The statistics module 524 may set the third average based on or equal to a sum of the number (e.g., 20) of the most recently stored values of the third temperature divided by the number (e.g., 20). The buffer module 508 stores the third average.

At 620, the buffer module 508 stores the sample of the fourth temperature (TD), and the statistics module 524 determines a fourth average of the number (e.g., 20) of the most recently stored values of the fourth temperatures (TD). The statistics module 524 may set the fourth average based on or equal to a sum of the number (e.g., 20) of the most recently stored values of the fourth temperature divided by the number (e.g., 20). The buffer module 508 stores the fourth average.

At 624, the statistics module 524 determines a first correlation coefficient (CorrA) based on the number (e.g., 20) of the most recently stored timestamps and the number (e.g., 20) of the most recently stored values of the first average. The first correlation coefficient may be, for example, the Pearson correlation coefficient. The statistics module 524 may determine the first correlation coefficient using the equation:

$$CorrA = \frac{Cov ( x , y )}{{σ}_{x} {σ}_{y}} ,$$

where CorrA is the first correlation coefficient, Cov(x,y) is the covariance of the most recently stored values of the first average (y) and the most recently stored timestamps (x), σ_{y} is the standard deviation of the most recently stored values of the first average (y), and σₓ is the standard deviation of the most recently stored timestamps (x).

At 628, the statistics module 524 determines σ_{y} the standard deviation of the number of the most recently stored values of the first average (y). At 632, the statistics module 524 determines σₓ the standard deviation of the number of the most recently stored values of the timestamps (x).

At 636, the statistics module 524 determines a first slope based on the first correlation coefficient, σₓ the standard deviation of the most recently stored timestamps (x), and σ_{y} the standard deviation of the most recently stored values of the first average (y). For example, the statistics module 524 may set the first slope using the equation:

SlopeA=CorrA*σ_{y}/σₓ,

where SlopeA is the first slope, CorrA is the first correlation coefficient, σₓ is the standard deviation of the most recently stored timestamps (x), and σ_{y} is the standard deviation of the most recently stored values of the first average (y).

At 640, the diagnostic module 528 determines whether the first slope is outside of a slope range. The slope range may be calibrated and may be, for example, approximately −1.0 to approximately +1.0 or another suitable range. If 640 is true, control continues with 700, which is discussed further below. If 640 is false, control transfers to 644.

At 644, the statistics module 524 determines a second correlation coefficient (CorrB) based on the number (e.g., 20) of the most recently stored timestamps and the number (e.g., 20) of the most recently stored values of the second average. The second correlation coefficient may be, for example, the Pearson correlation coefficient. The statistics module 524 may determine the second correlation coefficient using the equation:

$$CorrB = \frac{Cov ( x , y )}{{σ}_{x} {σ}_{y}} ,$$

where CorrB is the second correlation coefficient, Cov(x,y) is the covariance of the most recently stored timestamps (x) and the most recently stored values of the second average (y), σₓ is the standard deviation of the most recently stored timestamps (x), and σ_{y} is the standard deviation of the most recently stored values of the second average (y).

At 648, the statistics module 524 determines σ_{y} the standard deviation of the number of the most recently stored values of the second average (y). At 652, the statistics module 524 determines σₓ the standard deviation of the number of the most recently stored timestamps (x).

At 656, the statistics module 524 determines a second slope based on the second correlation coefficient, σₓ of the standard deviation of the most recently stored timestamps (x), and σ_{y} of the standard deviation of the most recently stored values of the second average (y). For example, the statistics module 524 may set the second slope using the equation:

SlopeB=CorrB*σ_{y}/σₓ,

where SlopeB is the second slope, CorrB is the second correlation coefficient, σ_{y} is the standard deviation of the most recently stored timestamps (x), and σₓ is the standard deviation of the most recently stored values of the second average (y).

At 660, the diagnostic module 528 determines whether the second slope is outside of the slope range (e.g., approximately −1.0 to approximately +1.0). If 660 is true, control continues with 700, which is discussed further below. If 660 is false, control transfers to 664.

At 664, the statistics module 524 determines a third correlation coefficient (CorrC) based on the number (e.g., 20) of the most recently stored timestamps and the number (e.g., 20) of the most recently stored values of the third average. The third correlation coefficient may be, for example, the Pearson correlation coefficient. The statistics module 524 may determine the third correlation coefficient using the equation:

$$CorrC = \frac{Cov ( x , y )}{{σ}_{x} {σ}_{y}} ,$$

where CorrC is the third correlation coefficient, Cov(x,y) is the covariance of the most recently stored timestamps (x) and the most recently stored values of the third average (y), σ_{y} is the standard deviation of the most recently stored timestamps (x), and σₓ is the standard deviation of the most recently stored values of the third average (y).

At 668, the statistics module 524 determines σ_{y} the standard deviation of the number of the most recently stored values of the third average (y). At 672, the statistics module 524 determines σₓ the standard deviation of the number of the most recently stored timestamps (x).

At 676, the statistics module 524 determines a third slope based on the third correlation coefficient, σₓ of the standard deviation of the most recently stored timestamps (x), and σ_{y} of the standard deviation of the most recently stored values of the third average (y). For example, the statistics module 524 may set the third slope using the equation:

SlopeC=CorrC*σ_{y}/σₓ,

where SlopeC is the third slope, CorrC is the third correlation coefficient, σₓ is the standard deviation of the most recently stored timestamps (x), and σ_{y} is the standard deviation of the most recently stored values of the third average (y).

At 680, the diagnostic module 528 determines whether the third slope is outside of the slope range (e.g., approximately −1.0 to approximately +1.0). If 680 is true, control continues with 700, which is discussed further below. If 680 is false, control transfers to 684.

At 684, the statistics module 524 determines a fourth correlation coefficient (CorrD) based on the number (e.g., 20) of the most recently stored timestamps and the number (e.g., 20) of the most recently stored values of the fourth average. The fourth correlation coefficient may be, for example, the Pearson correlation coefficient. The statistics module 524 may determine the fourth correlation coefficient using the equation:

$$CorrD = \frac{Cov ( x , y )}{{σ}_{x} {σ}_{y}} ,$$

where CorrD is the fourth correlation coefficient, Cov(x,y) is the covariance of the most recently stored timestamps (x) and the most recently stored values of the fourth average (y), σₓ is the standard deviation of the most recently stored timestamps (x), and σ_{y} is the standard deviation of the most recently stored values of the fourth average (y).

At 688, the statistics module 524 determines σ_{y} the standard deviation of the number of the most recently stored values of the fourth average (y). At 692, the statistics module 524 determines σₓ the standard deviation of the number of the most recently stored timestamps (x).

At 694, the statistics module 524 determines a fourth slope based on the fourth correlation coefficient, σₓ of the standard deviation of the number of the most recently stored timestamps (x), and σ_{y} of the standard deviation of the number of the most recently stored values of the fourth average (y). For example, the statistics module 524 may set the fourth slope using the equation:

SlopeD=CorrD*σ_{y}/σₓ,

where SlopeD is the third slope, CorrD is the fourth correlation coefficient, σₓ is the standard deviation of the number of the most recently stored timestamps (x), and σ_{y} is the standard deviation of the number of the most recently stored values of the fourth average (y).

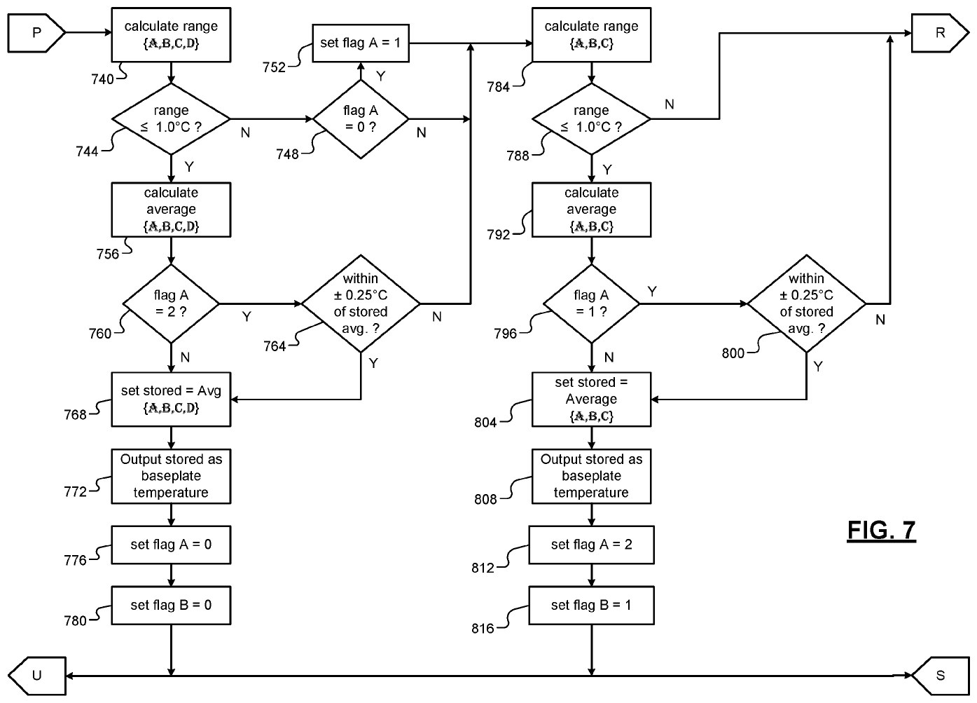

At 696, the diagnostic module 528 determines whether the fourth slope is outside of the slope range (e.g., approximately −1.0 to approximately +1.0). If 696 is true, control continues with 700. If 696 is false, the temperature of the baseplate is not rapidly changing, and control continues with 740 (via P) of FIG. 7.

At 700, the baseplate temperature module 512 determines whether the second signal (Flag B) is set to a first state, such as digital 0. The second signal being set to the first state indicates to the baseplate temperature module 512 to determine the baseplate temperature based on the measurements from all four of the temperature sensors 308. If 700 is false, control transfers to 708. If 700 is true, the baseplate temperature module 512 determines the baseplate temperature based on the first, second, third, and fourth averages at 704. This may bypass the verification of the precision of the temperature sensors 308 and may avoid the possible false identification of a fault when the baseplate temperature is changing rapidly. The baseplate temperature module 512 may, for example, set the baseplate temperature based on or equal to an average of the first, second, third, and fourth averages (determined at 608-620). The baseplate temperature module 512 outputs the baseplate temperature at 736, for example, to be used to determine the substrate temperature.

At 708, the baseplate temperature module 512 determines whether the second signal (Flag B) is set to a second state, such as digital 1. The second signal being set to the second state indicates to the baseplate temperature module 512 to determine the baseplate temperature based on the measurements from the first, second, and third ones of the temperature sensors 308. If 708 is false, control transfers to 716. If 708 is true, the baseplate temperature module 512 determines the baseplate temperature based on the first, second and third averages at 712. The baseplate temperature module 512 may, for example, set the baseplate temperature based on or equal to an average of the first, second and third averages (determined at 608-616). Control continues with 736.

At 716, the baseplate temperature module 512 determines whether the second signal (Flag B) is set to a third state, such as digital 2. The second signal being set to the third state indicates to the baseplate temperature module 512 to determine the baseplate temperature based on the measurements from the first, second, and fourth ones of the temperature sensors 308. If 716 is false, control transfers to 724. If 716 is true, the baseplate temperature module 512 determines the baseplate temperature based on the first, second, and fourth averages at 720.

The baseplate temperature module 512 may, for example, set the baseplate temperature based on or equal to an average of the first, second, and fourth averages (determined at 608, 612, and 620). Control continues with 736.

At 724, the baseplate temperature module 512 determines whether the second signal (Flag B) is set to a fourth state, such as digital 3. The second signal being set to the fourth state indicates to the baseplate temperature module 512 to determine the baseplate temperature based on the measurements from the first, third, and fourth ones of the temperature sensors 308. If 724 is true, the baseplate temperature module 512 determines the baseplate temperature based on the first, third, and fourth averages at 728. The baseplate temperature module 512 may, for example, set the baseplate temperature based on or equal to an average of the first, third, and fourth averages (determined at 608, 616, and 620). Control continues with 736. If 724 is false, the baseplate temperature module 512 determines the baseplate temperature based on the second, third, and fourth averages at 732. The baseplate temperature module 512 may, for example, set the baseplate temperature based on or equal to an average of the second, third, and fourth averages (determined at 612-620). Control continues with 736.

Referring now to FIG. 7, at 740 the statistics module 524 determines a first range of the first, second, third, and fourth averages. The statistics module 524 determines a minimum (least) one of the first, second, third, and fourth averages, and a maximum (greatest) one of the first, second, third, and fourth averages. The statistics module 524 sets the first range to a difference between the minimum and maximum ones of the first, second, third, and fourth averages.

At 744, the diagnostic module 528 determines whether the first range is less than the first temperature range (e.g., approximately 1 degree Celsius). If 744 is false, control continues with 748. If 744 is true, control continues with 756, which is discussed further below. At 748, the diagnostic module 528 determines whether the first signal (Flag A) is set to a first state, such as digital 0. The first signal being set to the first state may indicate that the measurements from all four of the temperature sensors 308 were being used to determine the baseplate temperature. If 748 is false, control transfers to 784, which is discussed further below. If 748 is true, the diagnostic module 528 sets the first signal (Flag A) to a second state, such as digital 1 at 752, and control continues with 784. The first signal being set to the second state may indicate that the determination of the baseplate temperature is transitioning from the use of all four of the temperature sensors 308 to less than all four of the temperature sensors 308.

At 756 (when 744 is true), the baseplate temperature module 512 determines an average temperature based on the first, second, third, and fourth averages. The baseplate temperature module 512 may, for example, set the average temperature based on or equal to an average of the first, second, third, and fourth averages (determined at 608-620).

At 760, the diagnostic module 528 determines whether the first signal (Flag A) is set to a third state, such as digital 2. If 760 is true, the diagnostic module 528 determines whether the average temperature determined at 756 is within the second temperature (e.g., approximately 0.5 degrees Celsius or 0.25 degrees Celsius) of a stored temperature at 764. The stored temperature is the last value of the baseplate temperature output by the baseplate temperature module 512. If 764 is false, control transfers to 784, which is discussed further below. If 764 is true, at 768 the baseplate temperature module 512 sets the stored temperature to the average temperature determined at 756. The baseplate temperature module 512 outputs the average temperature determined at 756 as the baseplate temperature at 772. 764 ensures that changes in the output baseplate temperature are limited to less than the second temperature. This may ensure that the temperature probe measurements do not induce a change in values depend on the determined baseplate temperature.

At 776, the diagnostic module 528 sets the first signal (Flag A) to the first state, such as digital 0. At 780, the diagnostic module 528 sets the second signal (Flag B) to the first state, such as digital 0. Control then returns to 604 for the next timestamp via U.

At 784, the statistics module 524 determines a second range of the first, second, and third averages. The statistics module 524 determines a minimum (least) one of the first, second, and third averages, and a maximum (greatest) one of the first, second, and third averages. The statistics module 524 sets the second range to a difference between the minimum and maximum ones of the first, second, and third averages.

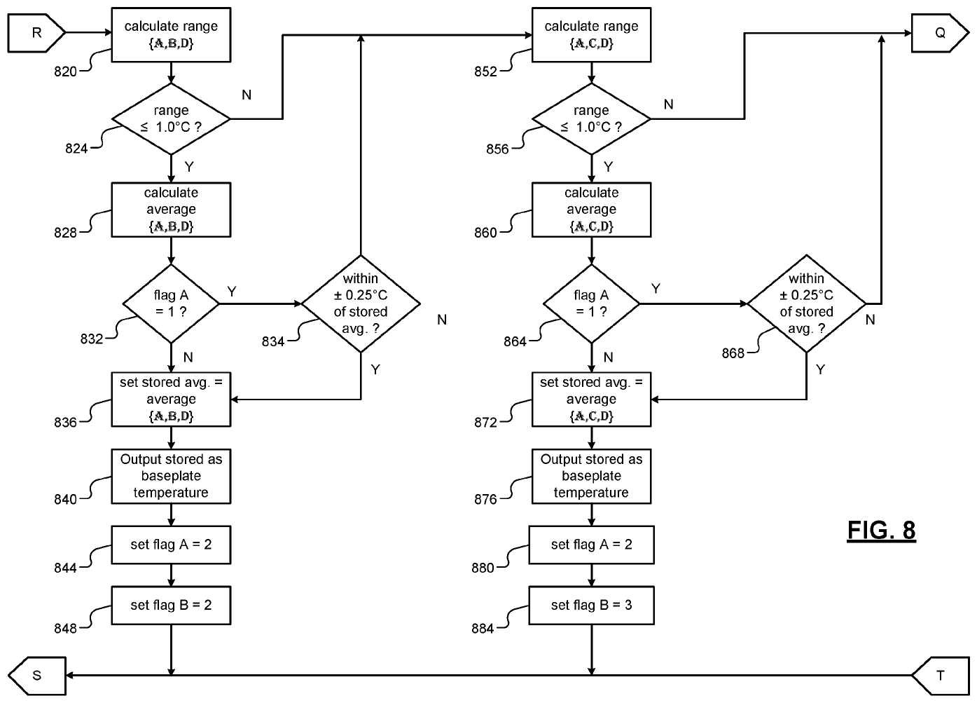

At 788, the diagnostic module 528 determines whether the second range is less than the first temperature range (e.g., approximately 1 degree Celsius). If 788 is false, control continues with 820 of FIG. 8 (via R), which is discussed further below. If 788 is true, control continues with 792.

At 792, the baseplate temperature module 512 determines the average temperature based on the first, second, and third averages. The baseplate temperature module 512 may, for example, set the average temperature based on or equal to an average of the first, second, and third averages (determined at 608-616).

At 796, the diagnostic module 528 determines whether the first signal (Flag A) is set to the second state, such as digital 1. If 796 is false, control continues with 804. If 796 is true, at 800 the diagnostic module 528 determines whether the average temperature determined at 792 is within the second temperature (e.g., approximately 0.5 degrees Celsius or 0.25 degrees Celsius) of the stored temperature. If 800 is false, control transfers to 820, which is discussed further below. If 800 is true, control continues with 804. At 804 the baseplate temperature module 512 sets the stored temperature to the average temperature determined at 792. At 808, the baseplate temperature module 512 outputs the average temperature determined at 792 as the baseplate temperature. 800 ensures that changes in the output baseplate temperature are limited to less than the second temperature.

At 812, the diagnostic module 528 sets the first signal (Flag A) to the third state, such as digital 2. At 816, the diagnostic module 528 sets the second signal (Flag B) to the second state, such as digital 1. Control then returns to 604 for the next timestamp via U.

Referring to 820 of FIG. 8, the statistics module 524 determines a third range of the first, second, and fourth averages. The statistics module 524 determines a minimum (least) one of the first, second, and fourth averages, and a maximum (greatest) one of the first, second, and fourth averages. The statistics module 524 sets the third range to a difference between the minimum and maximum ones of the first, second, and fourth averages.

At 824, the diagnostic module 528 determines whether the third range is less than the first temperature range (e.g., approximately 1 degree Celsius). If 824 is false, control continues with 852, which is discussed further below. If 824 is true, control continues with 828.

At 828, the baseplate temperature module 512 determines the average temperature based on the first, second, and fourth averages. The baseplate temperature module 512 may, for example, set the average temperature based on or equal to an average of the first, second, and fourth averages (determined at 608, 612, and 620).

At 832, the diagnostic module 528 determines whether the first signal (Flag A) is set to the second state, such as digital 1. If 832 is false, control continues with 836. If 832 is true, at 834, the diagnostic module 528 determines whether the average temperature determined at 828 is within the second temperature (e.g., approximately 0.5 degrees Celsius or 0.25 degrees Celsius) of the stored temperature. If 834 is false, control transfers to 852, which is discussed further below. If 834 is true, control continues with 836. At 836, the baseplate temperature module 512 sets the stored temperature to the average temperature determined at 828. At 840, the baseplate temperature module 512 outputs the average temperature determined at 828 as the baseplate temperature. 834 ensures that changes in the output baseplate temperature are limited to less than the second temperature.

At 844, the diagnostic module 528 sets the first signal (Flag A) to the third state, such as digital 2. At 848, the diagnostic module 528 sets the second signal (Flag B) to the third state, such as digital 2. Control then returns to 604 for the next timestamp via U.

At 852, the statistics module 524 determines a fourth range of the first, third, and fourth averages. The statistics module 524 determines a minimum (least) one of the first, third, and fourth averages, and a maximum (greatest) one of the first, third, and fourth averages. The statistics module 524 sets the fourth range to a difference between the minimum and maximum ones of the first, third, and fourth averages.

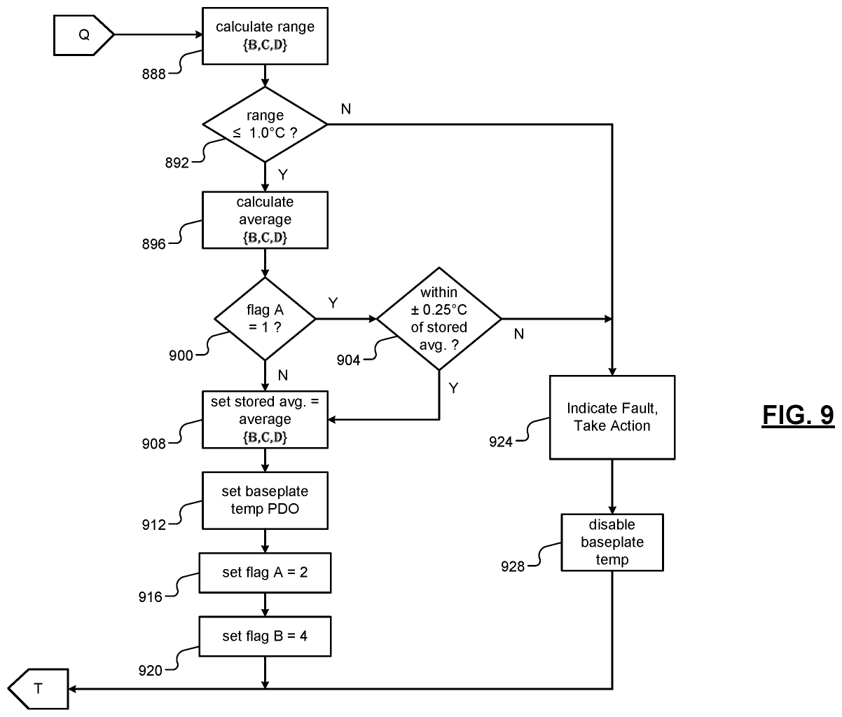

At 856, the diagnostic module 528 determines whether the fourth range is less than the first temperature range (e.g., approximately 1 degree Celsius). If 856 is false, control continues with 888 of FIG. 9 (via Q), which is discussed further below. If 856 is true, control continues with 860.

At 860, the baseplate temperature module 512 determines the average temperature based on the first, third, and fourth averages. The baseplate temperature module 512 may, for example, set the average temperature based on or equal to an average of the first, third, and fourth averages (determined at 608, 616, and 620).

At 864, the diagnostic module 528 determines whether the first signal (Flag A) is set to the second state, such as digital 1. If 864 is false, control continues with 872. If 864 is true, at 868, the diagnostic module 528 determines whether the average temperature determined at 860 is within the second temperature (e.g., approximately 0.5 degrees Celsius or 0.25 degrees Celsius) of the stored temperature. If 868 is false, control transfers to 888 of FIG. 9, which is discussed further below. If 868 is true, control continues with 872. At 872, the baseplate temperature module 512 sets the stored temperature to the average temperature determined at 860. At 876, the baseplate temperature module 512 outputs the average temperature determined at 860 as the baseplate temperature. 868 ensures that changes in the output baseplate temperature are limited to less than the second temperature.

At 880, the diagnostic module 528 sets the first signal (Flag A) to the third state, such as digital 2. At 884, the diagnostic module 528 sets the second signal (Flag B) to the fourth state, such as digital 3. Control then returns to 604 for the next timestamp via U.

Referring now to 888 of FIG. 9, the statistics module 524 determines a fifth range of the second, third, and fourth averages. The statistics module 524 determines a minimum (least) one of the second, third, and fourth averages, and a maximum (greatest) one of the second, third, and fourth averages. The statistics module 524 sets the fifth range to a difference between the minimum and maximum ones of the second, third, and fourth averages.

At 892, the diagnostic module 528 determines whether the fifth range is less than the first temperature range (e.g., approximately 1 degree Celsius). If 892 is false, no combination of three of the temperature sensors 308 is within the first temperature range, and control continues with 924, which is discussed further below. If 892 is true, control continues with 896.

At 896, the baseplate temperature module 512 determines the average temperature based on the second, third, and fourth averages. The baseplate temperature module 512 may, for example, set the average temperature based on or equal to an average of the second, third, and fourth averages (determined at 612-620).

At 900, the diagnostic module 528 determines whether the first signal (Flag A) is set to the second state, such as digital 1. If 900 is false, control continues with 908. If 900 is true, at 904 the diagnostic module 528 determines whether the average temperature determined at 896 is within the second temperature (e.g., approximately 0.5 degrees Celsius or 0.25 degrees Celsius) of the stored temperature. If 904 is false, control transfers to 924, which is discussed further below. If 904 is true, control continues with 908.

At 908, the baseplate temperature module 512 sets the stored temperature to the average temperature determined at 896. At 912, the baseplate temperature module 512 outputs the average temperature determined at 896 as the baseplate temperature. 904 ensures that changes in the output baseplate temperature are limited to less than the second temperature.

At 916, the diagnostic module 528 sets the first signal (Flag A) to the third state, such as digital 2. At 920, the diagnostic module 528 sets the second signal (Flag B) to the fifth state, such as digital 4. Control then returns to 604 for the next timestamp via T and U.

At 924, the diagnostic module 528 diagnoses the fault in the temperature probe 216. The diagnostic module 528 may also take one or more other actions. For example, the diagnostic module 528 may display a predetermined message associated with the fault in the temperature probe 216 on the display 526. Additionally or alternatively, the diagnostic module 528 may prompt the system control module 160 to stop the substrate processing. For example, the diagnostic module 528 may prompt the system control module 160 to actuate the gas delivery system 130 and stop the flow of one or more gasses to the processing chamber 102. Additionally or alternatively, the diagnostic module 528 may prompt the system control module 160 to adjust the RF generating system 120 to stop applying power to one, more than one, or all within the processing chamber 102. The diagnostic module 528 may disable the baseplate temperature module 512 at 928. Control may return to 604 via T and U or may wait until the fault is cleared or remediated.

While the example of the temperature probe 216 being associated with the baseplate 110 is provided, the above diagnostics and management is also applicable to the temperature sensors 204 being temperature probes. Also, while the example of the temperature probe 216 having four temperature sensors is provided, the temperature probe 216 may include more than four temperature sensors.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. A substrate processing system comprising:
a substrate support within a processing chamber to vertically support a substrate;
a temperature probe including:
a first temperature sensor to measure a first temperature of the substrate support;
a second temperature sensor to measure a second temperature of the substrate support;
a third temperature sensor to measure a third temperature of the substrate support; and
a fourth temperature sensor to measure a fourth temperature of the substrate support;
a temperature module to:
in a first state, determine a substrate support temperature of the substrate support based on all of the first, second, third, and fourth temperatures;
in a second state, determine the substrate support temperature of the substrate support based on only three of the first, second, third, and fourth temperatures;
a temperature control module configured to control at least one of heating and cooling of the substrate support based on the substrate support temperature;
a statistics module to determine a slope of a line based on a plurality of values of the first temperature; and
a diagnostic module to diagnose whether the slope is within a slope range.

2. The substrate processing system of claim 1 wherein the temperature module is to set the substrate support temperature based on an average of the at least three of the first, second, third, and fourth temperatures.

3. The substrate processing system of claim 1 wherein:
the substrate support includes:
an upper portion to vertically support the substrate; and
a baseplate to vertically support the upper portion;
the first temperature sensor is to measure the first temperature of the baseplate;
the second temperature sensor to measure the second temperature of the baseplate;
the third temperature sensor is to measure the third temperature of the baseplate; and
the fourth temperature sensor is to measure the fourth temperature of the baseplate.

4. The substrate processing system of claim 1 wherein:
the substrate support includes:
an upper portion to vertically support the substrate; and
a baseplate to vertically support the upper portion;
the first temperature sensor is to measure the first temperature of the upper portion;
the second temperature sensor to measure the second temperature of the upper portion;
the third temperature sensor is to measure the third temperature of the upper portion; and
the fourth temperature sensor is to measure the fourth temperature of the upper portion.

5. The substrate processing system of claim 1 wherein the temperature module is to determine the substrate support temperature based on at least three of:
a first average of X of the first temperatures, wherein X is an integer greater than one;
a second average of X of the second temperatures;
a third average of X of the third temperatures; and
a fourth average of X of the fourth temperatures.

6. The substrate processing system of claim 5 wherein the temperature module is to determine the substrate support temperature based on an average of the at least three of the first average, the second average, the third average, and the fourth average.

7. The substrate processing system of claim 5 wherein the temperature module is to determine the substrate support temperature based on all of the first, second, third, and fourth averages when a first difference between a maximum one of the first, second, third, and fourth averages and a minimum one of the first, second, third, and fourth averages is less than a temperature.

8. The substrate processing system of claim 7 wherein the temperature module is to selectively determine the substrate support temperature based on three of the first, second, third, and fourth averages when the first difference is greater than the substrate support temperature.

9. The substrate processing system of claim 8 wherein the temperature module is to determine the substrate support temperature based on the first, second, and third average and not based on the fourth average when a second difference between a second maximum one of the first, second, and third averages and a second minimum one of the first, second, and third averages is less than the substrate support temperature.

10. The substrate processing system of claim 9 wherein the temperature module is to determine the substrate support temperature based on the first, second, and fourth average and not based on the third average when a third difference between a third maximum one of the first, second, and fourth averages and a third minimum one of the first, second, and fourth averages is less than the substrate support temperature.

11. The substrate processing system of claim 10 wherein the temperature module is to determine the substrate support temperature based on the first, third, and fourth average and not based on the second average when a fourth difference between a fourth maximum one of the first, third, and fourth averages and a fourth minimum one of the first, third, and fourth averages is less than the substrate support temperature.

12. The substrate processing system of claim 11 wherein the temperature module is to determine the substrate support temperature based on the second, third, and fourth average and not based on the first average when a fifth difference between a fifth maximum one of the second, third, and fourth averages and a fifth minimum one of the second, third, and fourth averages is less than the substrate support temperature.

13. The substrate processing system of claim 12 further comprising a diagnostic module to indicate that a fault is present in the temperature probe when the first, second, third, fourth, and fifth differences are greater than the substrate support temperature.

14. The substrate processing system of claim 13 wherein the diagnostic module is to display an alert on a display when the fault is present in the temperature probe.

15. The substrate processing system of claim 1 wherein the first, second, third, and fourth temperature sensors are solid state temperature sensors.

16. The substrate processing system of claim 1 further comprising a thermally conductive material sandwiched between the substrate support and the first, second, third, and fourth temperature sensors.

17. The substrate processing system of claim 1 wherein the statistics module is to:
determine a first average of a plurality of values of the first temperature;
determine a second average of a plurality of values of the first average;
determine a first standard deviation of the plurality of values of the first average;
determine a second standard deviation of a plurality of timestamps associated with the plurality of values of the first average;
determine a correlation coefficient based on the plurality of timestamps and the plurality of values of the first average;
determine the slope of the line based on the correlation coefficient, the first standard deviation, and the second standard deviation.

18. The substrate processing system of claim 17 wherein the statistics module is to determine the correlation coefficient based on (a) a covariance of the plurality of values of the first average and the plurality of timestamps, (b) the first standard deviation, and (c) the second standard deviation.

19. The substrate processing system of claim 17 wherein the statistics module is to set the slope based on the correlation coefficient multiplied by the first standard deviation divided by the second standard deviation.

20. The substrate processing system of claim 1 wherein the temperature control module is to at least one of:
selectively apply power to a thermal control element (TCE) based on the substrate support temperature; and
selectively adjust coolant flow through coolant channels in the substrate support based on the substrate support temperature.

21. A substrate processing system comprising:
a substrate support within a processing chamber to vertically support a substrate;
a temperature probe including:
N temperature sensors to measure N temperatures of the substrate support, respectively,
wherein N is an integer greater than 3;
a temperature module to:
in a first state, determine a substrate support temperature of the substrate support based on all of the N temperatures;
in a second state, determine the substrate support temperature of the substrate support based on a subset of the N temperatures;
a temperature control module to control at least one of heating and cooling of the substrate support based on the substrate support temperature;
a statistics module to determine a slope of a line based on a plurality of values of one of the N temperatures; and
a diagnostic module to diagnose whether the slope is within a slope range.

22. A method comprising:
by a first temperature sensor of a temperature probe, measuring a first temperature of a substrate support that vertically supports a substrate during substrate processing;
by a second temperature sensor of the temperature probe, measuring a second temperature of the substrate support;
by a third temperature sensor of the temperature probe, measuring a third temperature of the substrate support;
by a fourth temperature sensor of the temperature probe, measuring a fourth temperature of the substrate support;
in a first state, determining a substrate support temperature of the substrate support based on all of the first, second, third, and fourth temperatures;
in a second state, determining the substrate support temperature of the substrate support based on only three of the first, second, third, and fourth temperatures; and
controlling at least one of heating and cooling of the substrate support based on the substrate support temperature;
determining a slope of a line based on a plurality of values of the first temperature; and
diagnosing whether the slope is within a slope range.

23. The method of claim 22 wherein determining the substrate support temperature includes setting the support temperature based on an average of the at least three of the first, second, third, and fourth temperatures.

24. The method of claim 22 wherein:
the substrate support includes:
an upper portion to vertically support the substrate; and
a baseplate to vertically support the upper portion;
the measuring the first temperature includes measuring the first temperature of the baseplate;
the measuring the second temperature includes measuring the second temperature of the baseplate;
the measuring the third temperature includes measuring the third temperature of the baseplate; and
the measuring the fourth temperature includes measuring the fourth temperature of the baseplate.

25. The method of claim 22 wherein:
the substrate support includes:
an upper portion to vertically support the substrate; and
a baseplate to vertically support the upper portion;
the measuring the first temperature includes measuring the first temperature of the upper portion;
the measuring the second temperature includes measuring the second temperature of the upper portion;
the measuring the third temperature includes measuring the third temperature of the upper portion; and
the measuring the fourth temperature includes measuring the fourth temperature of the upper portion.

26. The method of claim 22 wherein determining the substrate support temperature includes determining the substrate support temperature based on at least three of:
a first average of X of the first temperatures, wherein X is an integer greater than one;
a second average of X of the second temperatures;
a third average of X of the third temperatures; and
a fourth average of X of the fourth temperatures.

27. The method of claim 26 wherein determining the substrate support temperature includes determining the substrate support temperature based on an average of the at least three of the first average, the second average, the third average, and the fourth average.

28. The method of claim 26 wherein determining the substrate support temperature includes determining the substrate support temperature based on all of the first, second, third, and fourth averages when a first difference between a maximum one of the first, second, third, and fourth averages and a minimum one of the first, second, third, and fourth averages is less than a temperature.

29. The method of claim 28 determining the substrate support temperature includes determining the substrate support temperature based on three of the first, second, third, and fourth averages when the first difference is greater than the substrate support temperature.

30. The method of claim 29 wherein determining the substrate support temperature includes determining the substrate support temperature based on the first, second, and third average and not based on the fourth average when a second difference between a second maximum one of the first, second, and third averages and a second minimum one of the first, second, and third averages is less than the substrate support temperature.

31. The method of claim 30 wherein determining the substrate support temperature includes determining the substrate support temperature based on the first, second, and fourth average and not based on the third average when a third difference between a third maximum one of the first, second, and fourth averages and a third minimum one of the first, second, and fourth averages is less than the substrate support temperature.

32. The method of claim 31 wherein determining the substrate support temperature includes determining the substrate support temperature based on the first, third, and fourth average and not based on the second average when a fourth difference between a fourth maximum one of the first, third, and fourth averages and a fourth minimum one of the first, third, and fourth averages is less than the substrate support temperature.

33. The method of claim 32 wherein determining the substrate support temperature includes determining the substrate support temperature based on the second, third, and fourth average and not based on the first average when a fifth difference between a fifth maximum one of the second, third, and fourth averages and a fifth minimum one of the second, third, and fourth averages is less than the substrate support temperature.

34. The method of claim 33 further comprising indicating that a fault is present in the temperature probe when the first, second, third, fourth, and fifth differences are greater than the substrate support temperature.

35. The method of claim 34 further comprising displaying an alert on a display when the fault is present in the temperature probe.

36. The method of claim 22 wherein the first, second, third, and fourth temperature sensors are solid state temperature sensors.

37. The method of claim 22, wherein a thermally conductive material is sandwiched between the substrate support and the first, second, third, and fourth temperature sensors.

38. The method of claim 22 further comprising:
determining a first average of a plurality of values of the first temperature;
determining a second average of a plurality of values of the first average;
determining a first standard deviation of the plurality of values of the first average;
determining a second standard deviation of a plurality of timestamps associated with the plurality of values of the first average;
determining a correlation coefficient based on the plurality of timestamps and the plurality of values of the first average;
determining the slope of the line based on the correlation coefficient, the first standard deviation, and the second standard deviation.

39. The method of claim 38 wherein determining the correlation coefficient includes determining the correlation coefficient based on (a) a covariance of the plurality of values of the first average and the plurality of timestamps, (b) the first standard deviation, and (c) the second standard deviation.

40. The method of claim 38 wherein determining the slope includes setting the slope based on the correlation coefficient multiplied by the first standard deviation divided by the second standard deviation.

41. The method of claim 22 wherein controlling at least one of heating and cooling of the substrate support includes at least one of:
selectively applying power to a thermal control element (TCE) based on the substrate support temperature; and
selectively adjusting coolant flow through coolant channels in the substrate support based on the substrate support temperature.
